(19) United States
(12) Patent Application Publication
(10) Pub. No.: US 2024/0222518 A1
(43) Pub. Date: Jul. 4, 2024

(54) DISPLAY DEVICE

(71) Applicant: LG Display Co., Ltd., Seoul (KR)

(72) Inventors: JuHeyuck BAECK, Paju-si (KR); YoungHyun KO, Paju-si (KR); DoHyung LEE, Paju-si (KR); HongRak CHOI, Paju-si (KR); ChanYong JEONG, Paju-si (KR)

(21) Appl. No.: 18/540,557

(22) Filed: Dec. 14, 2023

(30) Foreign Application Priority Data
Dec. 29, 2022 (KR) 10-2022-0189237

(51) Int. Cl. H01L 29/786; H10K 59/121

(52) U.S. Cl. CPC H01L 29/7869; H01L 29/78633; H01L 29/78645; H10K 59/1213

(57) ABSTRACT

Embodiments of the present disclosure relate to a display device, which in more detail includes a substrate, a first gate electrode on the substrate, a first gate insulating film on the first gate electrode, an oxide semiconductor layer on the first gate insulating film, a second gate insulating film on the oxide semiconductor layer, a second gate electrode on the second gate insulating film, a first interface layer between the first gate insulating film and the oxide semiconductor layer, and a second interface layer between the second gate insulating film and the oxide semiconductor layer, wherein the first interface layer and the second interface layer contain mutually-different amounts of oxygen, thereby being able to provide a transistor structure having high reliability.

### CROSS-REFERENCE TO RELATED APPLICATION

This application claims priority from Korean Patent Application No. 10-2022-0189237, filed on Dec. 29, 2022, which is hereby incorporated by reference for all purposes as if fully set forth herein.

### BACKGROUND

### Technical Field

Embodiments of the present disclosure relate to a display device.

### Description of the Related Art

Transistors are widely used as switching devices and driving devices in the field of electronic devices.

Particularly, a thin film transistor can be manufactured on a glass substrate or a plastic substrate and is widely used as a driving device or a switching device in a display device such as a liquid crystal display device or an organic light emitting display device.

However, a transistor may deteriorate with an increase in a driving time, and, when deterioration of a transistor occurs, device reliability of the transistor may fall. In a case in which device reliability falls in accordance with deterioration of a transistor, image quality of a display device may also be degraded. Regarding this, technologies of various methods for improving or compensating for deterioration of transistors have been developed.

### BRIEF SUMMARY

Embodiments of the present disclosure can provide a display device including a device of a double-gate structure of a bidirectional channel that can be stably driven without a large change in a threshold voltage (Vth).

Embodiments of the present disclosure can provide a display device including a device of a double-gate structure of a bidirectional channel that can be stably driven without any change in a threshold voltage even in a case in which it is driven in an on-state for a long time.

Embodiments of the present disclosure can provide a display device including a device of a double-gate structure of a bidirectional channel having high reliability.

Embodiments of the present disclosure can provide a display device including a substrate, a first gate electrode on the substrate, a first gate insulating film on the first gate electrode, an oxide semiconductor layer on the first gate insulating film, a second gate insulating film on the oxide semiconductor layer, a second gate electrode on the second gate insulating film, a first interface layer between the first gate insulating film and the oxide semiconductor layer, and a second interface layer between the second gate insulating film and the oxide semiconductor layer.

In the display device according to embodiments of the present disclosure, the first interface layer and the second interface layer may include mutually-different amounts of oxygen.

In the display device according to embodiments of the present disclosure, the first interface layer may be an oxygen-insufficient area, and the second interface layer may be an oxygen-excess area.

In the display device according to embodiments of the present disclosure, the first interface layer and the second interface layer may contain silicon (Si), and an amount of silicon of the first interface layer may be larger than an amount of silicon of the second interface layer.

According to embodiments of the present disclosure, a display device including a device of a double-gate structure of a bidirectional channel that can be stably driven without a large change in a threshold voltage (Vth) can be provided.

According to embodiments of the present disclosure, a display device including a device of a double-gate structure of a bidirectional channel that can be stably driven without any change in a threshold voltage even in a case in which it is driven in an on-state for a long time can be provided.

According to embodiments of the present disclosure, a display device including a device of a double-gate structure of a bidirectional channel having high reliability can be provided.

### BRIEF DESCRIPTION OF THE SEVERAL VIEWS OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a schematic system configuration diagram of a display device according to embodiments of the present disclosure.

FIG. 2 is a diagram illustrating an example of system implementation of a display device according to embodiments of the present disclosure.

FIG. 3 is an equivalent circuit of a subpixel of a display device according to embodiments of the present disclosure.

FIG. 4 is a diagram illustrating another equivalent circuit of a subpixel of a display device according to embodiments of the present disclosure.

FIG. 5 is a schematic diagram illustrating a gate driving circuit disposed in a display device according to embodiments of the present disclosure.

FIG. 6 is a plan view of a partial area of a subpixel in a display device according to embodiments of the present disclosure.

FIG. 7 is a cross-sectional view illustrating an example of a cross-sectional structure of a thin film transistor taken along line A-B illustrated in FIG. 6.

FIGS. 8 and 9 are cross-sectional views illustrating other examples of a cross-sectional structure of a thin film transistor taken along line A-B illustrated in FIG. 6.

FIG. 10 is a band diagram of the thin film transistor illustrated in FIG. 7.

FIG. 11 is a SIMS analysis graph of the thin film transistor illustrated in FIG. 7.

FIG. 12 is a diagram illustrating an equivalent circuit of the thin film transistor illustrated in FIG. 7.

FIG. 13 is a cross-sectional view illustrating another example of a cross-sectional structure of a thin film transistor taken along line A-B illustrated in FIG. 6.

FIG. 14 is a graph illustrating an amount of change in a threshold voltage of a thin film transistor according to embodiments of the present disclosure.

FIG. 15 is a graph acquired by analyzing device reliability of a thin film transistor according to embodiments of the present disclosure.

FIG. 16 is a diagram illustrating a transfer curve, a threshold voltage (Vth), and mobility (μ) of the thin film transistor illustrated in FIG. 7.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to”, “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to,” “contact or overlap,” etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to the attached drawings.

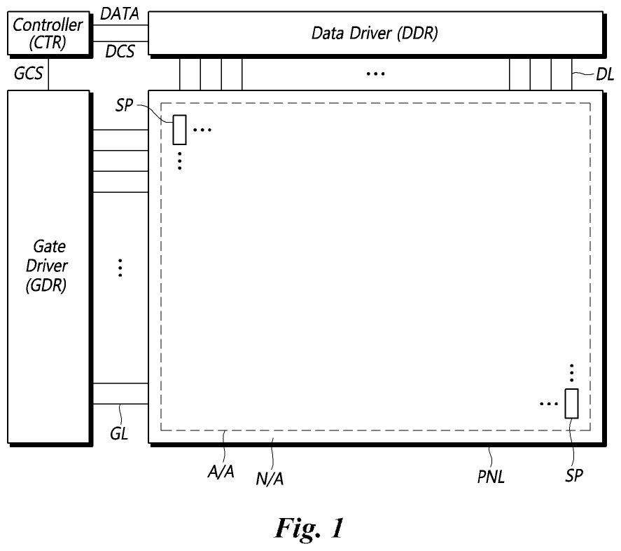

FIG. 1 is a schematic system configuration diagram of a display device according to embodiments of the present disclosure.

The display device according to embodiments of the present disclosure may include a display panel (PNL) displaying a video and outputting light and a driving circuit used for driving such a display panel (PNL).

In the display panel (PNL), multiple data lines (DL) and multiple gate lines (GL) are disposed, and multiple subpixels (SP) are connected to the multiple data lines (DL) and the multiple gate lines (GL) and, in some implementations, may be disposed in a matrix type. The multiple data lines (DL) and the multiple gate lines (GL) may be disposed to intersect each other.

In the display panel (PNL), in addition to the multiple data lines (DL) and the multiple gate lines (GL), signal wirings of different types may be disposed in accordance with a subpixel structure and the like. In addition, a drive voltage wiring, a reference voltage wiring, a common voltage wiring, or the like may be further disposed.

The types of signal wirings disposed in the display panel (PNL) may differ in accordance with a subpixel structure, a panel type, and the like. In description presented here, a signal wiring may have a concept including an electrode to which a signal is applied.

The display panel (PNL) may include a display region (A/A) in which an image (video) is displayed and a non-display region (N/A) that is an outskirt area thereof in which no image is displayed. Here, the non-display region (N/A) may also be referred to as a bezel arca.

In the display region (A/A), multiple subpixels (SP) for image display are disposed.

In the non-display region (N/A), a pad part used for electric connection of a data driver (DDR) is disposed, and multiple data link lines for connecting such a pad part and multiple data lines (DL) may be disposed. Here, the multiple data link lines may be parts of multiple data lines (DL) extended to the non-display region (N/A) or may be separate patterns electrically connected to multiple data lines (DL).

In addition, in the non-display region (N/A), through a pad part to which the data driver (DDR) is electrically connected, gate driving-related wirings used for delivering voltages (signals) required for gate driving to a gate driver (GDR) may be disposed. For example, the gate driving-related wirings may include clock wirings used for delivering clock signals, gate voltage wirings delivering gate voltages (VGH, VGL), gate driving control signals delivering various control signals required for generating scanning signals, and the like. Different from the gate lines (GL) disposed in the display region (A/A), such gate driving-related wirings are disposed in the non-display region (N/A).

The driving circuit may include a data driver (DDR) driving multiple data lines (DL), a gate driver (GDR) driving multiple gate lines (GL), a controller (CTR) controlling the data driver (DDR) and the gate driver (GDR), and the like.

The data driver (DDR) may drive multiple data lines (DL) by outputting data voltages to the multiple data lines (DL).

The gate driver (GDR) may drive multiple gate lines (GL) by outputting scanning signals to the multiple gate lines (GL).

The controller (CTR) may control driving operations of the data driver (DDR) and the gate driver (GDR) by supplying various control signals (DCS, GCS) required for the driving operations of the data driver (DDR) and the gate driver (GDR). In addition, the controller (CTR) may supply video data (DATA) to the data driver (DDR).

The controller (CTR) starts scanning in accordance with a timing implemented in each frame, converts input video data input from the outside in accordance with a data signal format used in the data driver (DDR), outputs the converted video data (DATA), and controls data driving at an appropriate time according to scanning.

In order to control the data driver (DDR) and the gate driver (GDR), the controller (CTR) receives timing signals such as a vertical synchronization signal (Vsync), a horizontal synchronization signal (Hsync), an input data enable (DE) signal, and a clock signal (CLK) from the outside (for example, a host system) as inputs, generates various control signals, and outputs the generated control signals to the data driver (DDR) and the gate driver (GDR).

For example, in order to control the gate driver (GDR), the controller (CTR) outputs various gate control signals (GCS) including a gate start pulse (GSP), a gate shift clock (GSC), a gate output enable signal (GOE), and the like.

In addition, in order to control the data driver (DDR), the controller (CTR) outputs various data control signals (DCS) including a source start pulse (SSP), a source sampling clock (SSC), a source output enable signal (SOE), and the like.

The controller (CTR) may be a timing controller used in a general display technology or a control device that includes a timing controller and can further perform other control functions.

The controller (CTR) may be implemented using a component that is separate from the data driver (DDR) or may be integrated with the data driver (DDR) and implemented as an integrated circuit.

The data driver (DDR) receives video data (DATA) from the controller (CTR) as an input and supplies data voltages to multiple data lines (DL), thereby driving the multiple data lines (DL). Here, the data driver (DDR) is also referred to as a source driver.

The data driver (DDR) may transmit/receive various signals to the controller (CTR) through various interfaces.

The gate driver (GDR) sequentially supplies scanning signals to multiple gate lines (GL), thereby sequentially driving the multiple gate lines (GL). Here, the gate driver (GDR) may also be referred to as a scanning driver.

The gate driver (GDR) sequentially supplies scanning signals of an on-voltage and an off-voltage to multiple gate lines (GL) in accordance with control of the controller (CTR).

When a specific gate line is opened by the gate driver (GDR), the data driver (DDR) converts video data (DATA) received from the controller (CTR) into data voltages of an analog form and supplies the data voltages to multiple data lines (DL).

The data driver (DDR) may be positioned on one side (for example, an upper side or a lower side) of the display panel (PNL) or may be positioned on both sides (for example, the upper side and the lower side) of the display panel (PNL) in accordance with a driving type, a panel design type, and the like according to circumstances.

The gate driver (GDR) may be positioned on one side (for example, a left side or a right side) of the display panel (PNL) or may be positioned on both sides (for example, the left side and the right side) of the display panel (PNL) in accordance with a driving type, a panel design type, and the like according to circumstances.

The data driver (DDR) may be implemented to include one or more source driver integrated circuits (SDIC).

Each source driver integrated circuit (SDIC) may include a shift register, a latch circuit, a digital to analog converter (DAC), an output buffer, and the like. In some cases, the data driver (DDR) may further include one or more analog to digital converters (ADC).

Each source driver integrated circuit (SDIC) may be connected to a bonding pad of the display panel (PNL) as a tape automated bonding (TAB) type or a chip on glass (COG) type or may be directly disposed on the display panel (PNL). In some cases, each source driver integrated circuit (SDIC) may be disposed to be integrated in the display panel (PNL). In addition, each source driver integrated circuit (SDIC) may be implemented as a chip-on-film (COF) type. In such a case, each source driver integrated circuit (SDIC) may be mounted on a circuit film and electrically connected to data lines (DL) of the display panel (PNL) through the circuit film.

The gate driver (GDR) may include multiple gate driving circuits (GDC). Here, the multiple gate driving circuits (GDC) respectively correspond to the multiple gate lines (GL).

Each gate driving circuit (GDC) may include a shift register, a level shifter, and the like.

Each gate driving circuit (GDC) may be connected to the bonding pad of the display panel (PNL) as a tape automated bonding (TAB) type or a chip on glass (COG) type. In addition, each gate driving circuit (GDC) may be implemented as a chip-on-film (COF) type. In such a case, each gate driving circuit (GDC) may be mounted on a circuit film and electrically connected to the gate lines (GL) of the display panel (PNL) through the circuit film. In addition, each gate driving circuit (GDC) may be implemented as a gate-in-panel (GIP) type and built into the display panel (PNL). In other words, each gate driving circuit (GDC) may be directly formed in the display panel (PNL).

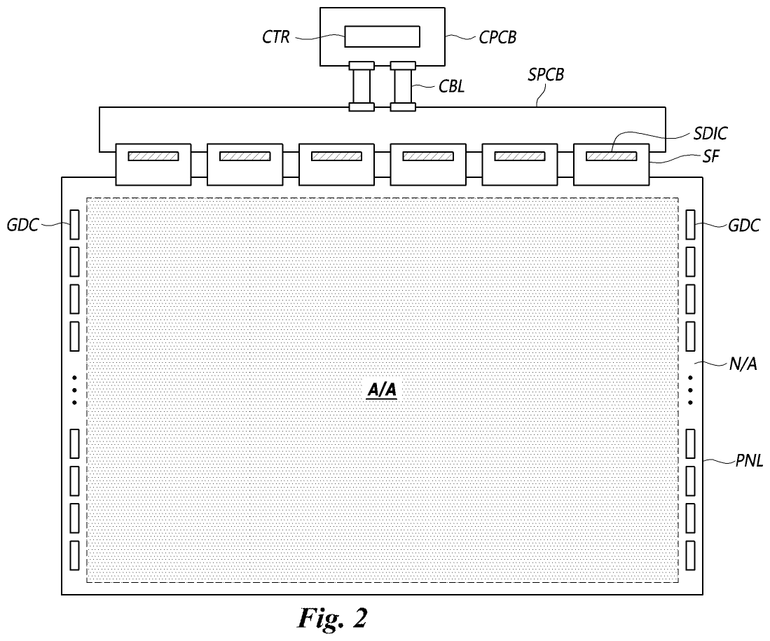

FIG. 2 is a diagram illustrating an example of system implementation of the display device according to embodiments of the present disclosure.

Referring to FIG. 2, in the display device according to embodiments of the present disclosure, the data driver (DDR) may be implemented as a chip-on-film type (COF) among various types (TAB, COG, COF, and the like), and the gate driver (GDR) may be implemented as a gate-in-panel type among various types (TAB, COG, COF, and the like).

The data driver (DDR) may be implemented as one or more source driver integrated circuits (SDIC). FIG. 2 illustrates an example in which the data driver (DDR) is implemented using multiple source driver integrated circuits (SDIC).

In a case in which the data driver (DDR) is implemented as the COF type, each source driver integrated circuit (SDIC) implementing the data driver (DDR) may be mounted on a source-side circuit film (SF).

One side of the source-side circuit film (SF) may be electrically connected to a pad part (an assembly body of pads) present in the non-display region (N/A) of the display panel (PNL).

On the source-side circuit film (SF), wirings used for electrically connecting the source driver integrated circuit (SDIC) and the display panel (PNL) to each other may be disposed.

For circuit connection between the multiple source driver integrated circuits (SDIC) and other devices, the display device may include one or more source printed circuit boards (SPCB) and a control printed circuit board (CPCB) for mounting control components and various electric devices.

The other side of the source-side circuit film (SF) in which the source driver integrated circuit (SDIC) is mounted may be connected to one or more source printed circuit boards (SPCB).

In other words, the source-side circuit film (SF) in which the source driver integrated circuit (SDIC) is mounted may have one side electrically connected to the non-display region (N/A) of the display panel (PNL) and the other side electrically connected to the source printed circuit board (SPCB).

In the control printed circuit board (CPCB), a controller (CTR) that controls operations of the data driver (DDR), the gate driver (GDR), and the like may be disposed.

In addition, in the control printed circuit board (CPCB), a power management integrated circuit (PMIC) that supplies various voltages or currents to the display panel (PNL), the data driver (DDR), the gate driver (GDR), and the like or controls various voltages or currents to be supplied, and the like may be disposed.

The source printed circuit board (SPCB) and the control printed circuit board (CPCB) may be connected as circuits through at least one connection member (CBL). Here, for example the connection member (CBL) may be a flexible printed circuit (FPC), a flexible flat cable (FFC), or the like.

One or more source printed circuit boards (SPCB) and the control printed circuit board (CPCB) may be implemented by being integrated as one printed circuit board.

In a case in which the gate driver (GDR) is implemented as a gate-in-panel (GIP) type, multiple gate driving circuits (GDC) included in the gate driver (GDR) may be directly formed on the non-display region (N/A) of the display panel (PNL).

Each of the multiple gate driving circuits (GDC) may output A corresponding scanning signal (SCAN) to a corresponding gate line (GL) disposed in the display region (A/A) of the display panel (PNL).

The multiple gate driving circuits (GDC) disposed on the display panel (PNL) may receive supply of various signals (a clock signal, a high-level gate voltage (VGH), a low-level gate voltage (VGL), a start signal (VST), a reset signal (RST), and the like) required for generating a scanning signal through gate driving-related wirings disposed in the non-display region (N/A).

The gate driving-related wirings disposed in the non-display region (N/A) may be electrically connected to the source-side circuit film (SF) that is disposed to be the most adjacent to multiple gate driving circuits (GDC).

The display device according to embodiments of the present disclosure may be a display including a back light unit such as a liquid crystal display device or a self-emission display such as an organic light emitting diode (OLED) display, a quantum dot display, or a micro light emitting diode (LED) display.

In a case in which the display device according to the embodiments of the present disclosure is an OLED display, each subpixel may include an organic light emitting diode (OLED) emitting light for itself as a light emitting device. In a case in which a display device according to the embodiments of the present disclosure is a quantum dot display, each subpixel (SP) may include a light emitting device formed using a quantum dot that is a semiconductor crystal emitting light for itself. In a case in which a display device according to the embodiments of the present disclosure is an LED display, each subpixel (SP) may include a micro light emitting diode (LED) that emits light for itself and is formed on the basis of an inorganic material as a light emitting device.

The display panel according to embodiments of the present disclosure may have either a top emission structure or a bottom emission structure and may have a dual emission structure in some cases.

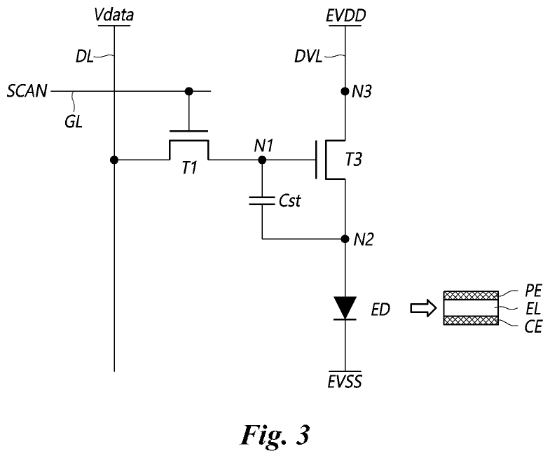

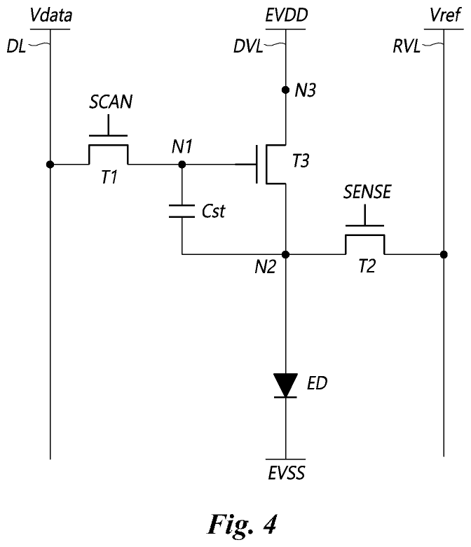

FIG. 3 is an equivalent circuit of a subpixel (SP) of the display device according to embodiments of the present disclosure, and FIG. 4 is another equivalent circuit of a subpixel of the display device according to embodiments of the present disclosure.

Referring to FIG. 3, each of multiple subpixels (SP) disposed in the display panel (PNL) of the display device according to embodiments of the present disclosure may include a light emitting device (ED), a drive transistor (T3), a scanning transistor (T1), and a storage capacitor (Cst).

Referring to FIG. 3, the light emitting device (ED) includes a pixel electrode (PE) and a common electrode (CE) and may include a light emitting layer (EL) positioned between the pixel electrode (PE) and the common electrode (CE).

The pixel electrode (PE) of the light emitting device (ED) is an electrode that is disposed for each subpixel (SP), and the common electrode (CE) may be an electrode that is disposed to be common to all the subpixels (SP). Here, the pixel electrode (PE) may be an anode electrode, and the common electrode (CE) may be a cathode electrode. To the contrary, the pixel electrode (PE) may be a cathode electrode, and the common electrode (CE) may be an anode electrode.

For example, the light emitting device (ED) may be an organic light emitting diode (OLED), a light emitting diode (LED), a quantum dot light emitting device, or the like.

A base voltage EVSS corresponding to a common voltage may be applied to the common electrode CE of the emitting device ED. Here, the base voltage EVSS may be, for example, a ground voltage or a voltage similar to the ground voltage.

The drive transistor (T3) is a transistor used for driving a light emitting device (ED) and may include a first node (N1), a second node (N2), a third node (N3), and the like. Here, the first node (N1) may be referred to as a first electrode, the second node (N2) may be referred to as a second electrode, and the third node (N3) may be referred to as a third electrode.

The first node (N1) of the drive transistor (T3) may be a gate node (gate electrode) of the drive transistor (T3) and electrically connected also to a source node or a drain node of the scanning transistor (T1).

The second node (N2) of the drive transistor (T3) may be a source node (source electrode) or a drain node (drain electrode) of the drive transistor (T3) and electrically connected to a pixel electrode (PE) of the light emitting device (ED).

The third node (N3) of the drive transistor (T3) may be a drain node (drain electrode) or a source node (source electrode) of the drive transistor (T3) and electrically connected to a drive voltage line (DVL) supplying a drive voltage (EVDD).

The scanning transistor (T1) is controlled in accordance with a scanning gate signal (SCAN) that is one type of gate signal and may be connected between the first node (N1) of the drive transistor (T3) and the data line (DL). In other words, the scanning transistor (T1) is turned on or turned off in accordance with a scanning gate signal (SCAN) supplied from a scanning gate line (SCL) that is one type of gate line (GL) and can control connection between the data line (DL) and the first node (N1) of the drive transistor (T3).

The scanning transistor (T1) is turned on in accordance with a scanning gate signal (SCAN) having a turn-on level voltage and can transfer a data voltage (Vdata) supplied from the data line (DL) to the first node (N1) of the drive transistor (T3).

Here, in a case in which the scanning transistor (T1) is an n-type transistor, the turn-on level voltage of the scanning gate signal (SCAN) may be a high-level voltage. In a case in which the scanning transistor (T1) is a p-type transistor, the turn-on level voltage of the scanning gate signal (SCAN) may be a low-level voltage.

The storage capacitor (Cst) may be connected between the first node (N1) and the second node (N2) of the drive transistor (T3). In the storage capacitor (Cst), an electric charge amount corresponding to a voltage difference between both ends is charged, and the storage capacitor (Cst) has a role for maintaining a voltage difference between both the ends for a set frame time. In accordance with this, a corresponding subpixel (SP) can emit light for the set frame time.

Referring to FIG. 4, each of multiple subpixels (SP) disposed in the display panel (PNL) of the display device according to embodiments of the present disclosure may further include a sensing transistor (T2).

The sensing transistor (T2) is controlled in accordance with a sensing gate signal (SENSE) that is one type of gate signal and may be connected between the second node (N2) of the drive transistor (T3) and a reference voltage line (RVL). In other words, the sensing transistor (T2) is turned on or turned off in accordance with a sensing gate signal (SENSE) supplied from a sensing gate line (SENL) that is another type of gate line (GL) and can control connection between the reference voltage line (RVL) and the second node (N2) of the drive transistor (T3).

The sensing transistor (T2) is turned on in accordance with a sensing gate signal (SENSE) having a turn-on level voltage and can transfer a reference voltage (Vref) supplied from the reference voltage line (RVL) to the second node (N2) of the drive transistor (T3).

In addition, the sensing transistor (T2) is turned on in accordance with a sensing gate signal (SENSE) having a turn-on level voltage and can transfer a voltage of the second node (N2) of the drive transistor (T3) to the reference voltage line (RVL).

Here, in a case in which the sensing transistor (T2) is an n-type transistor, the turn-on level voltage of the sensing gate signal (SENSE) may be a high-level voltage. In a case in which the sensing transistor (T2) is a p-type transistor, the turn-on level voltage of the sensing gate signal (SENSE) may be a low-level voltage.

The function of the sensing transistor (T2) to transfer the voltage of the second node (N2) of the drive transistor (T3) to the reference voltage line (RVL) may be used at the time of performing driving for sensing a characteristic value of the subpixel (SP). In such a case, the voltage transferred to the reference voltage line (RVL) may be a voltage used for calculating a characteristic value of the subpixel (SP) or a voltage in which the characteristic value of the subpixel (SP) is reflected.

Each of the drive transistor (T3), the scanning transistor (T1), and the sensing transistor (T2) may be either an n-type transistor or a p-type transistor. In the present disclosure, for convenience of description, a case in which each of the drive transistor (T3), the scanning transistor (T1), and the sensing transistor (T2) is the n-type will be described as an example.

The storage capacitor (Cst) may be not a parasitic capacitor (for example, Cgs or Cgd) that is an internal capacitor present between the gate node and the source node (or the drain node) of the drive transistor (T3) but an external capacitor that is intentionally designed outside the drive transistor (T3).

The scanning gate line (SCL) and the sensing gate line (SENL) may be mutually-different (e.g., different from one another) gate lines (GL). In such a case, the scanning gate signal (SCAN) and the sensing gate signal (SENSE) may be individual gate signals, and an on-off timing of the scanning transistor (T1) and an on-off timing of the sensing transistor (T2) disposed inside one subpixel (SP) may be independent from each other. In other words, the on-off timing of the scanning transistor (T1) and the on-off timing of the sensing transistor (T2) inside one subpixel (SP) may be the same or be different from each other.

Differently from this, the scanning gate line (SCL) and the sensing gate line (SENL) may be the same gate line (GL). In other words, a gate node of the scanning transistor (T1) and a gate node of the sensing transistor (T2) inside one subpixel (SP) may be connected to one gate line (GL). In such a case, the scanning gate signal (SCAN) and the sensing gate signal (SENSE) may be the same gate signal, and the on-off timing of the scanning transistor (T1) and the on-off timing of the sensing transistor (T2) inside one subpixel (SP) may be the same.

The structures of the subpixel (SP) illustrated in FIGS. 3 and 4 are examples and may be variously changed by further including one or more transistors and further including one or more capacitors.

Alternatively, multiple subpixels may have the same structure, or some of multiple subpixels may have a different structure.

In FIGS. 3 and 4, although the subpixel structures have been described by assuming a case in which the display device is a self-emission display device, in a case in which the display device is a liquid crystal display device, each subpixel (SP) may include a transistor, a pixel electrode, and the like.

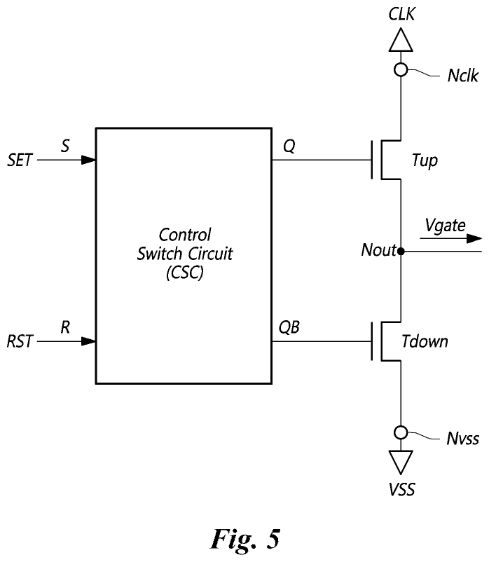

FIG. 5 is a diagram schematic illustrating a gate driving circuit (GDC) disposed in a display panel (PNL) according to embodiments of the present disclosure.

Referring to FIG. 5, each gate driving circuit (GDC) may include a pull-up transistor (Tup), a pull-down transistor (Tdown), a control switch circuit (CSC), and the like.

The control switch circuit (CSC) is a circuit that controls a voltage of a Q node corresponding to a gate node of the pull-up transistor (Tup) and a voltage of a QB node corresponding to a gate node of the pull-down transistor (Tdown) and may include several switches (transistors).

The pull-up transistor (Tup) is a transistor that supplies a gate signal (Vgate) corresponding to a first-level voltage (for example, a high-level voltage (VGH)) to a gate line (GL) through a gate signal output node (Nout). The pull-down transistor (Tdown) is a transistor that supplies a gate signal (Vgate) corresponding to a second-level voltage (for example, a low-level voltage (VGL)) to the gate line (GL) through the gate signal output node (Nout). The pull-up transistor (Tup) and the pull-down transistor (Tdown) may be turned on at different timings.

The pull-up transistor (Tup) is electrically connected between a clock signal application node (Nclk) to which a clock signal (CLK) is applied and a gate signal output node (Nout) electrically connected to the gate line (GL) and is turned on or turned off in accordance with the voltage of the Q node.

The gate node of the pull-up transistor (Tup) is electrically connected to the Q node. A drain node or a source node of the pull-up transistor (Tup) is electrically connected to the clock signal application node (Nelk). The source node or the drain node of the pull-up transistor (Tup) is electrically connected to the gate signal output node (Nout) from which a gate signal (Vgate) is output.

The pull-up transistor (Tup) is turned on in accordance with the voltage of the Q node and outputs a gate signal (Vgate) having a high-level voltage (VGH) in a high-level section of the clock signal (CLK) to the gate signal output node (Nout).

The gate signal (Vgate) of the high-level voltage (VGH) output to the gate signal output node (Nout) is supplied to a corresponding gate line (GL).

The pull-down transistor (Tdown) is electrically connected between the gate signal output node (Nout) and a ground voltage node (Nvss) and is turned on or turned off in accordance with a voltage of the QB node.

The gate node of the pull-down transistor (Tdown) is electrically connected to the QB node. A drain node or a source node of the pull-down transistor (Tdown) is electrically connected to the ground voltage node (Nvss) and is applied with a ground voltage (VSS) corresponding to a positive voltage. The source node or the drain node of the pull-down transistor (Tdown) is electrically connected to the gate signal output node (Nout) from which a gate signal (Vgate) is output.

The pull-down transistor (Tdown) is turned on in accordance with a voltage of the QB node and outputs a gate signal (Vgate) of the low-level voltage (VGL) to the gate signal output node (Nout). In accordance with this, the gate signal (Vgate) of the low-level voltage (VGL) can be supplied to a corresponding gate line (GL) through the gate signal output node (Nout). Here, for example, the gate signal (Vgate) of the low-level voltage (VGL) may be a ground voltage (VSS).

On the other hand, the control switch circuit (CSC) may be composed of two or more transistors, and there are main nodes such as a Q node, a QB node, a set node (S; also referred to as a start node), a reset node (R), and the like. In some cases, the control switch circuit (CSC) may further include an input node to which various voltages such as a drive voltage (VDD) and the like are input and the like.

In the control switch circuit (CSC), the Q node is electrically connected to the gate node of the pull-up transistor (Tup), and charging and discharging are repeated.

In the control switch circuit (CSC), the QB node is electrically connected to the gate node of the pull-down transistor (Tdown), and charging and discharging are repeated.

In the control switch circuit (CSC), the set node (S) is applied with a set signal (SET) for an instruction of start of gate driving of a corresponding gate driving circuit (GDC).

Here, the set signal (SET) applied to the set node (S) may be a start signal (VST) input from the outside of the gate driver (GDR) or may be a signal (carry signal) acquired by feeding back a gate signal (Vgate) output from the gate driving circuit (GDC) of a previous stage before the current gate driving circuit (GDC).

A reset signal (RST) applied to the reset node (R) in the control switch circuit (CSC) may be either a reset signal used for simultaneously initializing gate driving circuits (GDC) of all the stages or a carry signal input from another stage (a previous stage or a subsequent stage).

The control switch circuit (CSC) charges the Q node in response to a set signal (SET) and discharges the Q node in response to a reset signal (RST). The control switch circuit (CSC) may include an inverter circuit for charging or discharging the Q node and the QB node at mutually-different timings.

As illustrated in FIG. 3, in each of multiple subpixels (SP) inside the display region (A/A) of the display panel (PNL), a drive transistor (T3) and a switching transistor (O-SWT) may be disposed. However, these embodiments are not limited thereto, and, as illustrated in FIG. 4, three or more transistors may be disposed inside the display region (A/A) of the display panel (PNL).

As illustrated in FIG. 2, in a case in which the gate driving circuit (GDC) is implemented as the GIP type, in other words, in a case in which the gate driving circuit (GDC) is built into the display panel (PNL), various transistors (Tup, Tdown, and transistors of the inside of the CSC) configuring the gate driving circuit (GDC) as illustrated in FIG. 5 may be disposed in the non-display region (N/A) that is an outskirt area of the display region (A/A) of the display panel (PNL).

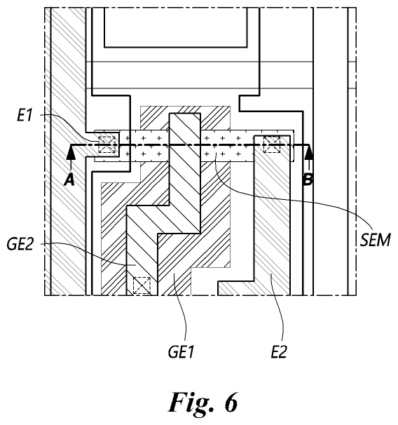

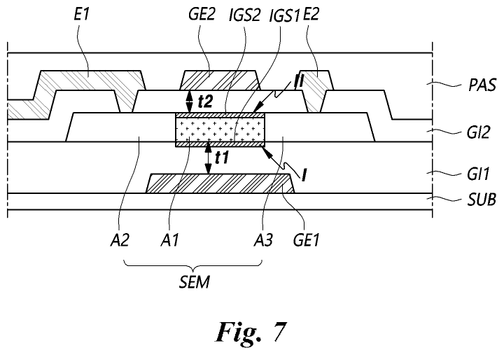

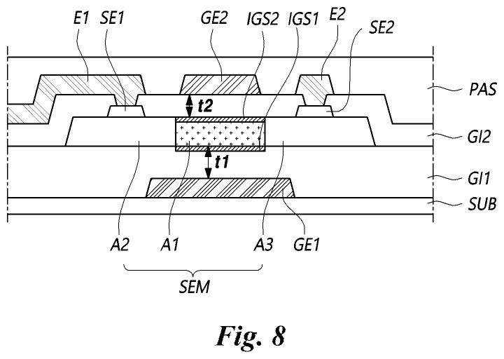

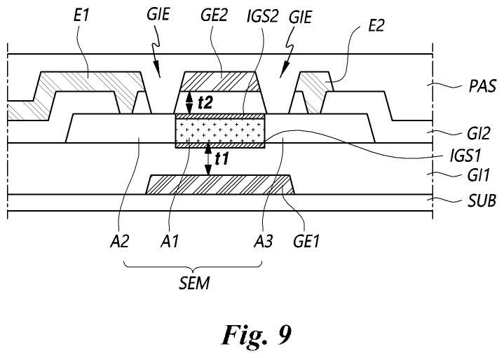

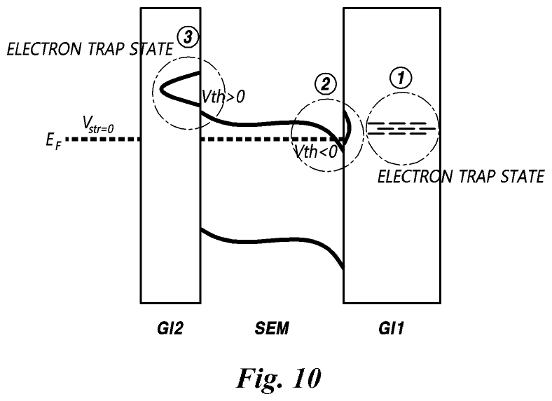

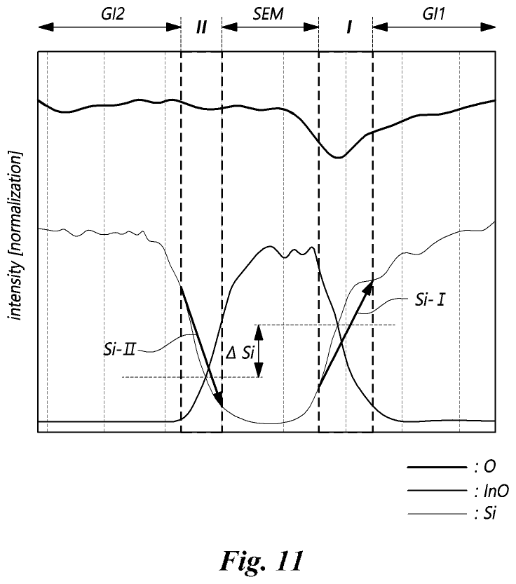

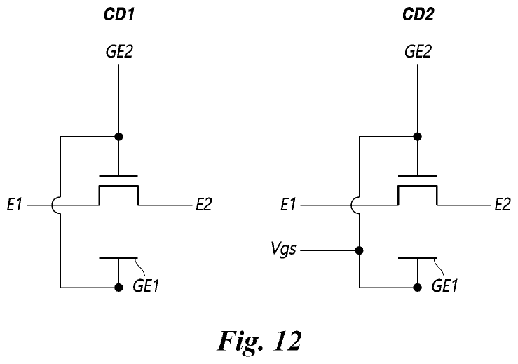

FIG. 6 is a plan view of a partial area of a subpixel in a display device according to embodiments of the present disclosure, and FIG. 7 is a cross-sectional view illustrating an example of a cross-sectional structure of a thin film transistor taken along line A-B illustrated in FIG. 6. FIGS. 8 to 9 are cross-sectional views illustrating other examples of a cross-sectional structure of a thin film transistor taken along line A-B illustrated in FIG. 6. FIG. 10 is a band diagram of the thin film transistor illustrated in FIG. 7. FIG. 11 is a SIMS analysis graph of the thin film transistor illustrated in FIG. 7. FIG. 12 is a diagram illustrating an equivalent circuit of the thin film transistor illustrated in FIG. 7.

Referring to FIG. 6, the thin film transistor (TFT) may include a first electrode (E1), a second electrode (E2), a first gate electrode (GE1), a second gate electrode (GE2), and a semiconductor layer (SEM). The first electrode (E1) may be a source electrode, and the second electrode (E2) may be a drain electrode. Differently from this, the first electrode (E1) may be a drain electrode, and the second electrode (E2) may be a source electrode. In description below, for the convenience of the description, an example in which the first electrode (E1) is the source electrode and the second electrode (E2) is the drain electrode will be described.

Referring to FIG. 7, the thin film transistor (TFT) formed in a display device according to embodiments of the present disclosure may include a first gate electrode (GE1), a first gate insulating film (GI1) on the first gate electrode (GE1), an oxide semiconductor layer (SEM) on the first gate insulating film (GI1), a second gate insulating film (GI2) on the oxide semiconductor layer (SEM), a second gate electrode (GE2) on the second gate insulating film (GI2), a first interface layer (IGS1) between the first gate insulating film (GI1) and the oxide semiconductor layer (SEM), and a second interface layer (IGS2) between the second gate insulating film (GI2) and the oxide semiconductor layer (SEM), and the first interface layer (IGS1) and the second interface layer (IGS2) may include different amounts of oxygen.

Referring to FIG. 7, the first gate electrode (GE1) may be disposed on a substrate (SUB). Under the first gate electrode (GE1), a buffer layer (not illustrated) may be disposed. The substrate (SUB) may be a glass substrate or a plastic substrate. The substrate (SUB) may be a flexible substrate, a bendable substrate, a stretchable substrate, or the like.

The first gate electrode (GE1) may contain any one of metals such as aluminum (Al), gold (Au), silver (Ag), copper (Cu), tungsten (W), molybdenum (Mo), chrome (Cr), tantalum (Ta), and titanium (Ti) or alloys thereof, but the present disclosure is not limited thereto.

Although the first gate electrode (GE1) is illustrated to have a single-layer structure in FIG. 7, the present disclosure is not limited thereto, and the first gate electrode (GE1) may have a multi-layer structure.

The first gate electrode (GE1) may take a role of a light shield layer (LS). Thus, a width of the first gate electrode (GE1) may be larger than a width of the channel region of the oxide semiconductor layer (SEM).

Referring to FIG. 7, the first gate insulating film (GI1) may be disposed on the first gate electrode (GE1). The first gate insulating film (GI1) may contain one or more inorganic insulation materials among silicon oxide (SiOx), silicon oxynitride (SiON), and silicon nitride (SiNx), but the present disclosure is not limited thereto.

The first gate insulating film (GI1) may be formed by depositing an inorganic insulation material in a high-temperature state, and when the inorganic insulation material is deposited in the high-temperature state, an electron trapping state of the inside the first gate insulating film (GI1) can be minimized.

In FIG. 7, although the first gate insulating film (GI1) is illustrated to have a single-layer structure, the present disclosure is not limited thereto, and the first gate insulating film (GI1) may have a multi-layer structure.

Referring to FIG. 7, an oxide semiconductor layer (SEM) may be disposed on the first gate insulating film (GI1).

The oxide semiconductor layer (SEM) may be composed of a metal oxide of zinc (Zn), indium (In), gallium (Ga), tin (Sn), titanium (Ti), and the like or a combination of metal such as zinc (Zn), indium (In), gallium (Ga), tin (Sn), or titanium (Ti) and an oxide thereof, but the present disclosure is not limited thereto. For example, the oxide semiconductor layer (SEM) may contain at least one of oxide zinc (ZnO), a zinc-tin oxide (ZTO, also stated at ZnSnO), a zinc-indium oxide (ZIO or ZnInO), an indium oxide (InO), a titanium oxide (TiO), an indium-gallium-zinc oxide (IGZO), and an indium-zinc-tin oxide (IZTO or InZnSnO), or Tin-oxide (SnO2) but the present disclosure is not limited thereto.

The thin film transistor (TFT) formed in the display device according to embodiments of the present disclosure may include a first conductor area (A2) positioned on one side of the oxide semiconductor layer (SEM) and a second conductor area (A3) positioned on the other side of the oxide semiconductor layer (SEM).

A channel region (A1) is formed between the first conductor area (A2) and the second conductor area (A3) of the oxide semiconductor layer (SEM).

The first conductor area (A2) may be electrically connected to the first electrode (E1), and the second conductor area (A3) may be electrically connected to the second electrode (E2).

Referring to FIG. 8, a first auxiliary electrode (SE1) between the first conductor area (A2) and the first electrode (E1) and a second auxiliary electrode (SE2) between the second conductor area (A3) and the second electrode (E2) may be included.

Referring to FIG. 7, a second gate insulating film (GI2) may be disposed on the oxide semiconductor layer (SEM). The second gate insulating film (GI2) may contain one or more inorganic insulation material among a silicon oxide (SiOx), silicon oxynitride (SiON), and silicon nitride (SiNx), but the disclosure is not limited thereto.

The second gate insulating film (GI2) may be deposited using atomic layer deposition ALD of an inorganic insulation material.

In FIG. 7, although the second gate insulating film (GI2) is illustrated to have a single-layer structure, the present disclosure is not limited thereto, and the second gate insulating film (GI2) may have a multi-layer structure.

Referring to FIG. 7, the second gate insulating film (GI2) may be disposed to extend between the first electrode (E1) and the second gate electrode (GE2), and the second gate insulating film (GI2) may be disposed to extend between the second electrode (E2) and the second gate electrode (GE2).

In other words, in the display device according to embodiments of the present disclosure, the thin film transistor (TFT) may have a structure in which the second gate insulating film (GI2) is not etched between an area in which the first electrode (E1) and the first conductor area (A2) are brought into contact with each other and the channel region (A1) and between an area in which the second electrode (E2) and the second conductor area (A3) are brought into contact with each other and the channel region (A1) (hereinafter, also referred to as a gate insulating film-etchless (GI etchless) structure)).

In a case in which the second gate insulating film of the thin film transistor (TFT) has a gate insulating film-etchless structure, after the second gate insulating film is formed on the semiconductor layer, a conductor area of the semiconductor layer may be formed using an ion doping process.

In accordance with this, the semiconductor layer (SEM) of the thin film transistor (TFT) can be prevented from being lost, and a contact portion between the first electrode (E1) and the first conductor area (A2) and a contact portion between the second electrode (E2) and the second conductor area (A3) in the thin film transistor (TFT) can be prevented from being damaged.

Referring to FIG. 9, the second gate insulating film (GI2) may be disposed to be discontinuous between the first electrode (E1) and the second gate electrode (GE2), and the second gate insulating film (GI2) may be disposed to be discontinuous between the second electrode (E2) and the second gate electrode (GE2).

In other words, in the display device according to embodiments of the present disclosure, the thin film transistor (TFT) may have a structure in which the second gate insulating film (GI2) is etched between an area in which the first electrode (E1) and the first conductor area (A2) are brought into contact with each other and the channel region (A1) and between an area in which the second electrode (E2) and the second conductor area (A3) are brought into contact with each other and the channel region (A1) (hereinafter, also referred to as a gate insulating film-etching (GI etching) structure; GIE).

In a case in which the second gate insulating film of the thin film transistor (TFT) has the gate insulating film-etching structure (GIE), after a second gate insulating film is formed on the semiconductor layer, a conductor area of the semiconductor layer may be formed in a dry etching process.

In embodiments of the present disclosure, the first gate insulating film (GI1) and the second gate insulating film (GI2) may contain the same inorganic insulation material. In addition, the first gate insulating film (GI1) and the second gate insulating film (GI2) may contain mutually-different (e.g., different from one another) inorganic insulation material.

Referring to FIG. 7, although a thickness (t1) of the first gate insulating film (GI1) may be larger than a thickness (t2) of the second gate insulating film (GI2), the present disclosure is not limited thereto, and the thickness (t2) of the second gate insulating film (GI2) may be larger than the thickness (t1) of the first gate insulating film (GI1).

Referring to FIG. 7, a second gate electrode (GE2) may be disposed on the second gate insulating film (GI2).

The second gate electrode (GE2) may contain any one of metals such as aluminum (Al), gold (Au), silver (Ag), copper (Cu), tungsten (W), molybdenum (Mo), chrome (Cr), tantalum (Ta), and titanium (Ti) or alloys thereof, but the present disclosure is not limited thereto.

In FIG. 7, although the second gate electrode (GE2) is illustrated to have a single-layer structure, the present disclosure is not limited thereto, and the second gate electrode (GE2) may have a multi-layer structure.

The first gate electrode (GE1) and the second gate electrode (GE2) may be electrically connected to each other to form a double-gate structure.

Referring to FIG. 12, CD1 illustrated on the left side is an equivalent circuit of a structure in which the first gate electrode (GE1) and the second gate electrode (GE2) are electrically connected to each other, and CD2 illustrated on the right side is an equivalent circuit of a structure in which a power supply to which a synchronized gate voltage (Vgs) is applied is electrically connected to the first gate electrode (GE1) and the second gate electrode (GE2) forming a double-gate structure.

Referring to FIG. 7, a first interface layer (IGS1) may be disposed between the first gate insulating film (GI1) and the oxide semiconductor layer (SEM), and a second interface layer (IGS2) may be disposed between the second gate insulating film (GI2) and the oxide semiconductor layer (SEM). For example, the first interface layer (IGS1) and the second interface layer (IGS2) may be disposed at positions overlapping the channel region (A1) of the oxide semiconductor layer (SEM). The first interface layer (IGS1) may be generally considered a insulator, but it might have some semiconductor properties since it is the interface layer between the first gate insulating film GI1 and the oxide semiconductor. Similarly, the second interface layer (IGS2) may be generally considered an insulator, but it might have some semiconductor properties since it is the interface layer between the second gate insulating film GI2 and the oxide semiconductor.

The first interface layer (IGS1) and the second interface layer (IGS2) may contain mutually-different (e.g., different from one another) amounts of oxygen.

In such a case, the first interface layer (IGS1) may be an oxygen-insufficient arca, and the second interface layer (IGS2) may be an oxygen-excess area, but the present disclosure is not limited thereto. In other words, the first interface layer (IGS1) may be an oxygen-excess arca, and the second interface layer (IGS2) may be an oxygen-insufficient area.

The first interface layer (IGS1) being an oxygen-insufficient area and the second interface layer (IGS2) being an oxygen-excess area may represent that an amount of oxygen by weight generally included in the first interface layer (IGS1) is smaller than the amount of oxygen by weight generally included in the second interface layer (IGS2). Thus even though both layers IGS1 and IGS2 might be the same material, such as SiO₂, since one layer is oxygen insufficient, some of the molecules might be missing an O in IGS1 and some might have an extra O in IGS2, yet overall these layers both are primarily SiO₂. Namely the layer IGS1 might be comprise of silicon oxide (SiOx), in which the x value might vary to be 1.8 or 1.9 in some portions of the layer that are oxygen insufficient and x might be 2.3 or 2.4 or higher in some portions of the layer in which oxygen is in excess. The same can occur if the gate insulator is oxynitride (SiON), or silicon nitride (SiNx). in which the relative amount of one or more of Silicon or Oxygen will vary slightly with respect to each other.

In the first interface layer (IGS1), after a first gate insulating film (GI1) is deposited, a SiH4 plasma process may be performed on an area in which a channel region of the oxide semiconductor layer (SEM) is to be formed. As a result, a first interface layer (IGS1) including an oxygen-insufficient area may be formed. This can be accomplished by forming a mask over all locations in which the semiconductor will be formed except area A1 that will be the channel when the plasma process is performed.

The first interface layer (IGS1) is not formed by additionally stacking it on the first gate insulating film (GI1) but is a part in which oxygen is insufficient in a part of the thickness of the first gate insulating film (GI1) by performing surface processing on the surface of the first gate insulating film (GI1) using SiH4 plasma.

In a case in which the first interface layer (IGS1) is an oxygen-insufficient arca, in a lower channel region of the oxide semiconductor layer (SEM) in the double-gate structure, a shift characteristic of a threshold voltage (Vth) being negative (−) may be implemented.

In a case in which the second interface layer (IGS2) is an oxygen-excess area, in an upper channel region of the oxide semiconductor layer (SEM) in the double-gate structure, a shift characteristic of a threshold voltage (Vth) being positive (+) may be implemented.

In the second interface layer (IGS2), after the oxide semiconductor layer (SEM) is deposited, an N₂O plasma process may be performed on an area in which a channel region of the oxide semiconductor layer (SEM) is to be formed. As a result, the second interface layer (IGS2) including an oxygen excess area can be formed. This can be accomplished by forming a mask over all locations in which the semiconductor is present except area A1 that will be the channel when the plasma process is performed.

The second interface layer (IGS2) is not formed by additionally stacking it on the oxide semiconductor layer (SEM) but is a part in which oxygen is excessively contained in a part of the thickness of the oxide semiconductor layer (SEM) by performing surface processing on the surface of the oxide semiconductor layer (SEM) using N₂O plasma.

Referring to FIG. 10, an area (1) of a band diagram is a first gate insulating film (GI1) formed by depositing an inorganic insulation material at a high-temperature state and can minimize an electron trap state inside the first gate insulating film (GI1). In other words, trapping that may cause positive deterioration (PBTS deterioration) of the thin film transistor is minimized, whereby PBTS deterioration can be inhibited.

Referring to FIG. 10, an area (2) of the band diagram is a first interface layer (IGS1) taking the role of shifting the threshold voltage (Vth) of the thin film transistor in a negative (−) direction, and an area (3) of the band diagram is a second interface layer (IGS2) taking the role of shifting the threshold voltage (Vth) of the thin film transistor in a positive (+) direction.

In accordance with this, in the thin film transistor according to embodiments of the present disclosure, a device of a double-gate structure in which, an effect of shifting the threshold voltage (Vth) in the negative (−) direction and an effect of shifting the threshold voltage in the positive (+) direction are offset, and variations in the threshold voltage (Vth) not in a uni-direction but in bi-directions in the channel region are suppressed can be provided. Thus, the thin film transistor according to embodiments of the present disclosure can be stably driven without a large change in the threshold voltage (Vth). Particularly, also in a case in which the thin film transistor is driven in the on state for a long time, the thin film transistor can be stably driven without any change in the threshold voltage.

On the other hand, a band diagram illustrated in FIG. 10 corresponds to a case in which, in the thin film transistor illustrated in FIG. 7, the thickness (t1) of the first gate insulating film (GI1) is larger than the thickness (T2) of the second gate insulating film (GI2). In a case in which the thickness (t2) of the second gate insulating film (GI2) is larger than the thickness (t1) of the first gate insulating film (GI1), band alignment of upper and lower diagrams may be implemented to be configured to be symmetrical (opposite) to each other.

The first interface layer (IGS1) and the second interface layer (IGS2) may contain silicon (Si), and the amount of silicon of the first interface layer (IGS1) may be larger than the amount of silicon of the second interface layer (IGS2).

Referring to FIG. 10, the amount of silicon of the first interface layer (IGS1) may represent an amount of silicon at an intermediate point of the first interface layer (IGS1) in a direction from an interface adjacent to the oxide semiconductor layer (SEM) to an interface adjacent to the first gate insulating film (GI1), and the amount of silicon of the second interface layer (IGS2) may represent an amount of silicon at an intermediate point of the second interface layer (IGS2) in a direction from the interface adjacent to the first gate insulating film (GI1) to the interface adjacent to the oxide semiconductor layer (SEM).

The amount of silicon of the first interface layer (IGS1) and the amount of silicon of the second interface layer (IGS2) may have inclinations according to depths of the first interface layer (IGS1) and the second interface layer (IGS2). For example, the amount of silicon of the first interface layer (IGS1) may increase (a Si-I direction) in a direction from the interface adjacent to the oxide semiconductor layer (SEM) to the interface adjacent to the first gate insulating film (GI1), and the amount of silicon of the second interface layer (IGS2) may decrease (a Si-II direction) in a direction from the interface adjacent to the second gate insulating film (GI2) to the interface adjacent to the oxide semiconductor layer (SEM).

Referring to FIG. 11, it can be checked that the amount of oxygen of area I in which the first interface layer (IGS1) is positioned is smaller than the amount of oxygen of area II in which the second interface layer (IGS2) is positioned, and the amount of silicon of the area I in which the first interface layer (IGS1) is positioned is larger than the amount of silicon of the area II in which the second interface layer (IGS2) is positioned.

In other words, by adjusting the amounts of silicon included in the first interface layer (IGS1) and the second interface layer (IGS2), the amounts of oxygen included in the first interface layer (IGS1) and the second interface layer (IGS2) can be adjusted. In addition, by adjusting the amount of oxygen, a positive (+) shift and a negative (−) shift of the threshold voltage (Vth) can be adjusted. In accordance with this, in the thin film transistor according to embodiments of the present disclosure, a device of a double-gate structure in which, an effect of shifting the threshold voltage (Vth) in the negative (−) direction and an effect of shifting the threshold voltage in the positive (+) direction are offset, and changes in the threshold voltage (Vth) in a channel region not in a uni-direction but in bi-directions are suppressed can be provided.

Referring to FIG. 7, a protection layer (PAS) may be disposed on the second gate electrode (GE2). The protection layer (PAS) may contain one or more inorganic insulation materials among a silicon oxide (SiOx), silicon oxynitride (SiON), and a silicon nitride (SiNx), but the present disclosure is not limited thereto.

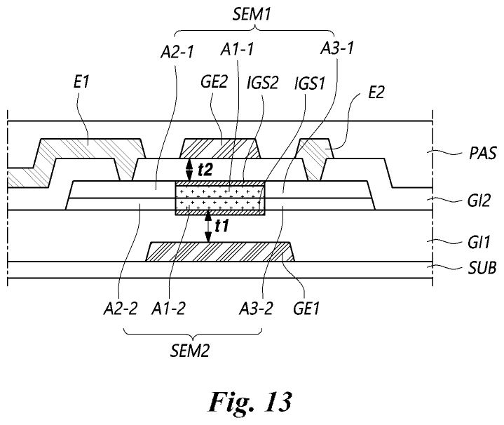

FIG. 13 is a cross-sectional view illustrating another example of a cross-sectional structure of a thin film transistor taken along line A-B illustrated in FIG. 6.

In the following description, details (configurations, effects, and the like) that are duplicates of those of the embodiments described above may be omitted.

Referring to FIG. 13, the thin film transistor (TFT) formed in the display device according to embodiments of the present disclosure may include a first gate electrode (GE1), a first gate insulating film (GI1) on the first gate electrode (GE1), an oxide semiconductor layer (SEM) on the first gate insulating film (GI1), a second gate insulating film (GI2) on the oxide semiconductor layer (SEM), a second gate electrode (GE2) on the second gate insulating film (GI2), a first interface layer (IGS1) between the first gate insulating film (GI1) and the oxide semiconductor layer (SEM), and a second interface layer (IGS2) between the second gate insulating film (GI2) and the oxide semiconductor layer (SEM), and the first interface layer (IGS1) and the second interface layer (IGS2) may contain mutually-different amounts of oxygen.

Referring to FIG. 13, the oxide semiconductor layer (SEM) may include a first oxide semiconductor layer (SEM1) and a second oxide semiconductor layer (SEM2).

The first oxide semiconductor layer (SEM1) may include a first channel region (A1-1), a (1-1)-th conductor area (A2-1) positioned on one side of the first channel region (A1-1), and a (2-1)-th conductor area (A3-1) positioned on the other side of the first channel region (A1-1). The second oxide semiconductor layer (SEM2) may include a second channel region (A1-2), a (1-2)-th conductor area (A2-2) positioned on one side of the second channel region (A1-2), and a (2-2)-th conductor area (A3-2) positioned on the other side of the second channel region (A1-2).

Referring to FIG. 13, the first interface layer (IGS1) and the second interface layer (IGS2) may be disposed at positions for overlapping the first channel region (A1-1) of the first oxide semiconductor layer (SEM1) and the second channel region (A1-2) of the second oxide semiconductor layer (SEM2).

Each of the first oxide semiconductor layer (SEM1) and the second oxide semiconductor layer (SEM2) may be composed of a metal oxide of zinc (Zn), indium (In), gallium (Ga), tin (Sn), titanium (Ti), and the like or a combination of metal such as zinc (Zn), indium (In), gallium (Ga), tin (Sn), or titanium (Ti) and an oxide thereof, but the present disclosure is not limited thereto. For example, each of the first oxide semiconductor layer (SEM1) and the second oxide semiconductor layer (SEM2) may contain at least one of oxide zinc (ZnO), a zinc-tin oxide (ZTO), a zinc-indium oxide (ZIO), an indium oxide (InO), a titanium oxide (TiO), an indium-gallium-zinc oxide (IGZO), and an indium-zinc-tin oxide (IZTO), but the present disclosure is not limited thereto. The relative ratios of each of the different types of oxide semiconductors will vary between the first oxide semiconductor layer (SEM1) and the second oxide semiconductor layer (SEM2). Thus, the amount of oxygen, by atomic weight in these layers will vary.

The first oxide semiconductor layer (SEM1) may be disposed adjacent to the first gate insulating film, and the second oxide semiconductor layer (SEM2) may be disposed adjacent to the second gate insulating film.

For example, the first interface layer (IGS1) may be disposed between the first gate insulating film (GI1) and the first oxide semiconductor layer (SEM1), and the second interface layer (IGS2) may be disposed between the second gate insulating film (GI2) and the second oxide semiconductor layer (SEM2).

The first oxide semiconductor layer (SEM1) and the second oxide semiconductor layer (SEM2) may contain the same material, and the first gate insulating film (GI1) and the second gate insulating film (GI2) may contain the same material.

The first oxide semiconductor layer (SEM1) and the second oxide semiconductor layer (SEM2) may contain the same material, and the first gate insulating film (GI1) and the second gate insulating film (GI2) may contain mutually-different (e.g., different from one another) materials.

The first oxide semiconductor layer (SEM1) and the second oxide semiconductor layer (SEM2) may contain mutually-different (e.g., different from one another) materials, and the first gate insulating film (GI1) and the second gate insulating film (GI2) may contain the same material.

The first oxide semiconductor layer (SEM1) and the second oxide semiconductor layer (SEM2) may contain mutually-different materials, and the first gate insulating film (GI1) and the second gate insulating film (GI2) may contain mutually-different materials.

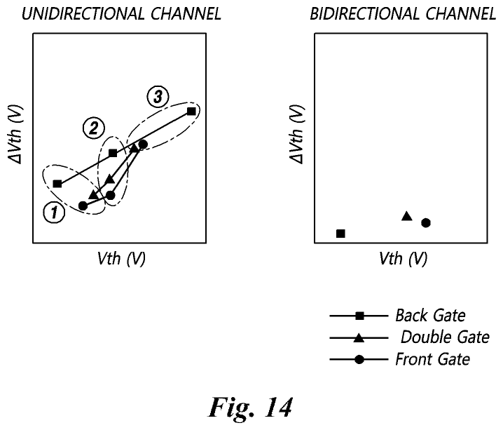

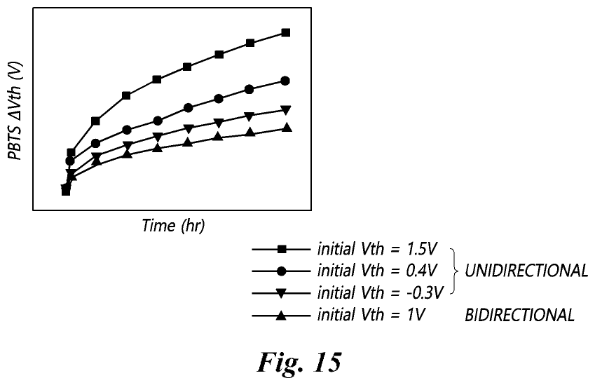

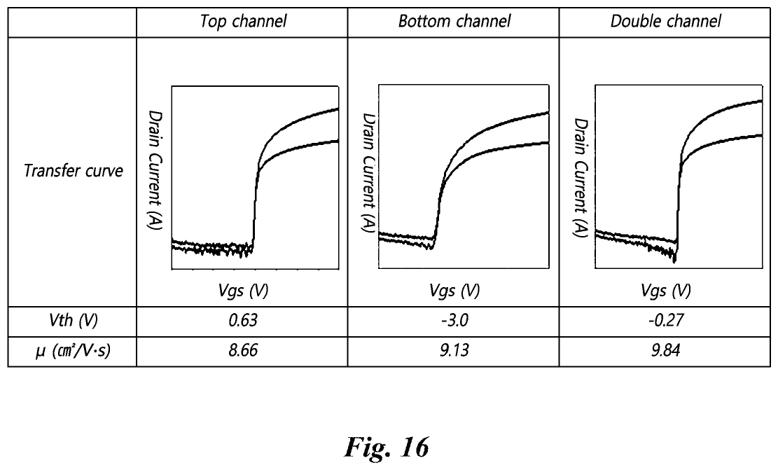

FIG. 14 is a graph illustrating an amount of change in a threshold voltage of another thin film transistor according to embodiments of the present disclosure. FIG. 15 is a graph acquired by analyzing device reliability of a thin film transistor according to embodiments of the present disclosure. FIG. 16 is a diagram illustrating a transfer curve, a threshold voltage (Vth), and mobility (μ) of the thin film transistor according to embodiments of the present disclosure.

Referring to FIG. 14, a graph representing a threshold voltage (Vth) and an amount of change (ΔVth) of the threshold voltage in a unidirectional channel that is a comparative example is illustrated on the left side as a comparative example, and a graph representing a threshold voltage (Vth) and an amount of change (ΔVth) of the threshold voltage in a bidirectional channel according to embodiments of the present disclosure is illustrated on the right side.

It can be checked that an amount of change (ΔVth) of a threshold voltage according to the threshold voltage (Vth) in a device of an top-gate structure, a device of a bottom-gate structure, or a device of a double-gate structure in a bidirectional channel device according to embodiments of the present disclosure is smaller than an amount of change (ΔVth) of a threshold voltage according to the threshold voltage (Vth) in a device of a top-gate structure, a device of a bottom-gate structure, or a device of a double-gate structure in a unidirectional channel device.

Therefore, the thin film transistor according to embodiments of the present disclosure can be stably driven without a large change of a threshold voltage (Vth).

Referring to FIG. 15, it can be checked that the amount of change (ΔVth) of the threshold voltage is large in a case in which a device of a unidirectional channel that is a comparative example is driven in an on-state for a long time. On the other, even in a case in which a device of a bidirectional double-gate structure according to embodiments of the present disclosure is driven in the on-state for a long time, it can be checked that the amount of change (ΔVth) of the threshold voltage is small.

Therefore, even in a case in which the thin film transistor according to embodiments of the present disclosure is driven in the on-state for a long time, the thin film transistor can be stably driven without a large change of the threshold voltage (Vth).

Referring to FIG. 16, in the thin film transistor according to embodiments of the present disclosure, it can be checked that a threshold voltage (Vth) of an upper channel region is shifted in a positive (+) direction, and a threshold voltage (Vth) of a lower channel region is shifted in a negative (−) direction. As a result, it can be checked that an effect of shifting the threshold voltage in the negative (−) direction and an effect of shifting the threshold voltage in the positive (+) direction are offset, and the threshold voltage (Vth) is approximately close to 0 in a double-channel region.

Thus, the thin film transistor according to embodiments of the present disclosure can provide a device of a double-gate structure of a bidirectional channel that can be stably driven without a large change of the threshold voltage (Vth).

In addition, the thin film transistor according to embodiments of the present disclosure can provide a device of a double-gate structure of a bidirectional channel that can be stably driven without any change of the threshold voltage even in the case of being driven in the on-state for a long time.

In addition, the thin film transistor according to embodiments of the present disclosure can provide a device of a double-gate structure of a bidirectional channel having high reliability.

Embodiments of the present disclosure described above will be briefly described as below.

A display device according to embodiments of the present disclosure may include a substrate, a first gate electrode on the substrate, a first gate insulating film on the first gate electrode, an oxide semiconductor layer on the first gate insulating film, a second gate insulating film on the oxide semiconductor layer, a second gate electrode on the second gate insulating film, a first interface layer between the first gate insulating film and the oxide semiconductor layer, and a second interface layer between the second gate insulating film and the oxide semiconductor layer, wherein the first interface layer and the second interface layer contain mutually-different amounts of oxygen.

The first interface layer and the second interface layer may include mutually-different amounts of oxygen.

The first interface layer may be an oxygen-insufficient area, and the second interface layer may be an oxygen-excess area.

The first interface layer and the second interface layer may contain silicon (Si), and an amount of silicon of the first interface layer may be larger than an amount of silicon of the second interface layer.

The amount of silicon of the first interface layer may increase in a direction from an interface adjacent to the oxide semiconductor layer to an interface adjacent to the first gate insulating film.

The amount of silicon of the second interface layer may decrease in a direction from an interface adjacent to the second gate insulating film to the interface adjacent to the oxide semiconductor layer.

In the display device according to embodiments of the present disclosure, a thickness of the first gate insulating film may be larger than a thickness of the second gate insulating film.

The first gate insulating film and the second gate insulating film may contain one or more of silicon oxide (SiOx), silicon oxynitride (SiON), and silicon nitride (SiNx).

The first gate insulating film and the second gate insulating film may contain the same material.

The first gate insulating film and the second gate insulating film may contain mutually-different materials.

In the display device according to embodiments of the present disclosure, the oxide semiconductor layer may include a first oxide semiconductor layer and a second oxide semiconductor layer, and the first oxide semiconductor layer may be disposed adjacent to the first gate insulating film, and the second oxide semiconductor layer may be disposed adjacent to the second gate insulating film.

The first oxide semiconductor layer and the second oxide semiconductor layer may contain the same material, and the first gate insulating film and the second gate insulating film contain the same material.

The first oxide semiconductor layer and the second oxide semiconductor layer may contain the same material, and the first gate insulating film and the second gate insulating film may contain mutually-different materials.

The first oxide semiconductor layer and the second oxide semiconductor layer may contain mutually-different materials, and the first gate insulating film and the second gate insulating film may contain the same material.

The first oxide semiconductor layer and the second oxide semiconductor layer may contain mutually-different materials, and the first gate insulating film and the second gate insulating film may contain mutually-different materials.

A first electrode and a second electrode electrically connected to both ends of the oxide semiconductor layer may be included.

The oxide semiconductor layer may include a channel region, and the channel region, the first interface layer and the second interface layer may be positioned to overlap each other.

A first conductor area positioned on one side of the oxide semiconductor layer and a second conductor area positioned on the other side of the oxide semiconductor layer may be included, and a first electrode electrically connected to the first conductor area and a second electrode electrically connected to the second conductor area may be included.

A first auxiliary electrode between the first conductor area and the first electrode and a second auxiliary electrode between the second conductor area and the second electrode may be included.

The second gate insulating film may be disposed to extend between the first electrode and the second gate electrode, and the second gate insulating film may be disposed to extend between the second electrode and the second gate electrode.

The second gate insulating film may be disposed to be discontinuous between the first electrode and the second gate electrode, and the second gate insulating film may be disposed to be discontinuous between the second electrode and the second gate electrode.

The first gate electrode and the second gate electrode may be electrically connected to each other.

The first gate electrode may be a light shield layer.

In the description herein, the amount of oxygen and the amount of silicon referred to amounts of oxygen (or silicon) by total atomic mass of that particular element within the relevant layers. For example, the statement that the first interface layer (IGS1) and the second interface layer (IGS2) include different amounts of an element is measured by the total atomic mass of that item within that particular layer. Thus, oxygen, as measured by total atomic mass of it within the first interface layer (IGS1) and the second interface layer (IGS2) are different from each other. The oxygen can be in any form within that oxide semiconductor layer, for example, it can be a part of an oxide zinc (ZnO), a zinc-tin oxide (ZTO), a zinc-indium oxide (ZIO), an indium oxide (InO), a titanium oxide (TiO), an indium-gallium-zinc oxide (IGZO), an indium-zinc-tin oxide (IZTO) or the like. As can be appreciated, if the oxide semiconductor is ZnO, semiconductor, then oxygen makes up half of the atoms and makes up about 20% of the mass of that layer about since the atomic weight of O is about 16 and one molecule of ZnO has an atomic weight of 81. On the other hand, in the oxide semiconductor of ZTO or ZIO, oxygen is only one of three elements in the molecule. For ZTO, the oxygen makes up only about 8% by weight of this layer since a molecule of ZTO has an atomic weight of about 200 and O has weight of 16. Thus, the amount of oxygen by atomic weight in each of the various oxide semiconductor layers is different and by varying the different types and amounts of the various oxide semiconductors in each layer, the amount of oxygen by atomic weight in that layer will vary.

Similarly, the first gate insulating film (GI1) may contain one or more inorganic insulation materials among silicon oxide (SiOx), silicon oxynitride (SiON), and silicon nitride (SiNx) and the relative amount of each of oxygen and silicon. Each of these have a different layers have different relative amounts of oxygen and silicon based on relative atomic weight of each. Thus, the atomic weight of oxygen in the layer IGS1 will be different than the atomic weight of oxygen in the layer IGS2. As can be appreciated, the same variations that of x that occur in the silicon oxide SiOₓ that might will be different from 2 can also occur in the oxide semiconductors.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles described herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate;
a first gate electrode on the substrate;
a first gate insulating film on the first gate electrode;
an oxide semiconductor layer on the first gate insulating film;
a second gate insulating film on the oxide semiconductor layer;
a second gate electrode on the second gate insulating film;
a first interface layer between the first gate insulating film and the oxide semiconductor layer; and
a second interface layer between the second gate insulating film and the oxide semiconductor layer,
wherein the first interface layer and the second interface layer contain different amounts of oxygen from one another.

2. The display device according to claim 1, wherein the first interface layer is an oxygen-insufficient area, and the second interface layer is an oxygen-excess area.

3. The display device according to claim 2,
wherein the first interface layer and the second interface layer contain silicon (Si), and
wherein an amount of silicon of the first interface layer is larger than an amount of silicon of the second interface layer.

4. The display device according to claim 3,
wherein the amount of silicon of the first interface layer increases in a direction from a first interface adjacent to the oxide semiconductor layer to a second interface adjacent to the first gate insulating film, and
wherein the amount of silicon of the second interface layer decreases in a direction from a third interface adjacent to the second gate insulating film to a fourth interface adjacent to the oxide semiconductor layer.

5. The display device according to claim 1, wherein a thickness of the first gate insulating film is greater than a thickness of the second gate insulating film.

6. The display device according to claim 5, wherein the first gate insulating film and the second gate insulating film contain one or more of silicon oxide (SiOx), silicon oxynitride (SiON), or silicon nitride (SiNx).

7. The display device according to claim 6, wherein the first gate insulating film and the second gate insulating film contain a same material.

8. The display device according to claim 6, wherein the first gate insulating film and the second gate insulating film contain different materials from one another.

9. The display device according to claim 1,
wherein the oxide semiconductor layer includes a first oxide semiconductor layer and a second oxide semiconductor layer, and
wherein the first oxide semiconductor layer is disposed adjacent to the first gate insulating film, and the second oxide semiconductor layer is disposed adjacent to the second gate insulating film.

10. The display device according to claim 9,
wherein the first oxide semiconductor layer and the second oxide semiconductor layer contain a same material, and
wherein the first gate insulating film and the second gate insulating film contain a same material.

11. The display device according to claim 9,
wherein the first oxide semiconductor layer and the second oxide semiconductor layer contain a same material, and
wherein the first gate insulating film and the second gate insulating film contain different materials from one another.

12. The display device according to claim 9,
wherein the first oxide semiconductor layer and the second oxide semiconductor layer contain different materials from one another, and
wherein the first gate insulating film and the second gate insulating film contain a same material.

13. The display device according to claim 9,
wherein the first oxide semiconductor layer and the second oxide semiconductor layer contain different materials from one another, and
wherein the first gate insulating film and the second gate insulating film contain different materials from one another.

14. The display device according to claim 1,
wherein the oxide semiconductor layer includes a channel region, and
wherein the channel region, the first interface layer and the second interface layer overlap each other.

15. The display device according to claim 1, further comprising:
a first conductor area positioned on a first side of the oxide semiconductor layer;
a second conductor area positioned on a second side of the oxide semiconductor layer;
a first electrode electrically connected to the first conductor area; and
a second electrode electrically connected to the second conductor area.

16. The display device according to claim 15, further comprising:
a first auxiliary electrode between the first conductor area and the first electrode; and
a second auxiliary electrode between the second conductor area and the second electrode.

17. The display device according to claim 15,
wherein the second gate insulating film extends between the first electrode and the second gate electrode, and
wherein the second gate insulating film extends between the second electrode and the second gate electrode.

18. The display device according to claim 15,
wherein the second gate insulating film is discontinuous between the first electrode and the second gate electrode, and
wherein the second gate insulating film is discontinuous between the second electrode and the second gate electrode.

19. The display device according to claim 1, wherein the first gate electrode and the second gate electrode are electrically connected to each other.

20. The display device according to claim 1, wherein the first gate electrode includes a light shield material.

21. A display device, comprising:
a substrate;
a first gate electrode on the substrate;
a first gate insulating film on the first gate electrode;
an oxide semiconductor layer on the first gate insulating film;
a second gate insulating film on the oxide semiconductor layer, the second gate insulating film having a lesser thickness than the first gate insulating film;
a second gate electrode on the second gate insulating film;
a first interface layer between the first gate insulating film and the oxide semiconductor layer; and
a second interface layer between the second gate insulating film and the oxide semiconductor layer.

22. The display device of claim 21, wherein the first interface layer includes a first amount of silicon, the second interface layer includes a second amount of silicon, and the first amount is greater than the second amount.

23. The display device of claim 21, wherein the first interface layer includes a first amount of oxygen, the second interface layer includes a second amount of oxygen, and the first amount is smaller than the second amount.
